(19) United States
(12) Patent Application Publication
(10) Pub. No.: US 2026/0212873 A1
(43) Pub. Date: Jul. 23, 2026

(54) AUDIO TECHNIQUES

(71) Applicants: David Michael Ronan, London (GB); Queen Mary University Of London, London (GB)

(72) Inventors: David Michael Ronan, London (GB); Joshua Daniel Reiss, London (GB)

(73) Assignees: Queen Mary University Of London, London (GB); David Michael Ronan, London (GB)

(21) Appl. No.: 19/142,353

(22) PCT Filed: Dec. 20, 2023
(86) PCT No.: PCT/GB2023/053325

§ 371 Date: Jun. 23, 2025

(30) Foreign Application Priority Data
Dec. 22, 2022 (GB) 2219481.5

(51) Int. Cl. G10L 19/008; H03G 3/30

(52) U.S. Cl. CPC G10L 19/008; H03G 3/3089

(57) ABSTRACT

Disclosed herein is a method of determining a plurality of inter-track auditory masking measurements between a plurality of audio tracks, the method comprising: dividing each audio track into a first set of frequency bands; and determining, for each frequency band of each audio track, an inter-track auditory masking measurement that is a measure of the masking between the frequency band of the audio track and a combination of the corresponding frequency bands of all of the other audio tracks; wherein each inter-track auditory masking measurement is determined in dependence on a psychoacoustic model.

### FIELD OF THE INVENTION

The present invention relates to audio techniques.

### BACKGROUND

Audio applications such as live broadcasts, live-action video games, teleconferencing and smart headphones may require a plurality of audio tracks to be mixed together. A known problem that may occur when mixing audio tracks is masking. Masking is when the presence of one sound makes another sound difficult to hear. Masking can reduce the quality of mixed audio tracks. There is a general need to improve on known techniques for automatically mixing audio tracks.

Audio mastering is typically the final step when preparing an audio recording for release. Audio mastering is usually performed manually by a mastering engineer who requires highly specialised skills and knowledge. There is a general desire for a high quality automatic mastering system.

### SUMMARY OF THE INVENTION

Aspects of the invention are set out in the appended independent claims. Optional aspects are set out in the dependent claims.

### DESCRIPTION OF THE DRAWINGS

The present invention will now be described, by way of non-limitative example only, with reference to the following figures, in which:

FIG. 1 shows a flowchart of a method according to an embodiment;

FIG. 2 shows a flowchart of a method according to an embodiment; and

FIG. 3 shows a flowchart of a method according to an embodiment.

### DETAILED DESCRIPTION

A first embodiment provides techniques for improving the mixing of multiple audio tracks.

An audio track comprises an audio signal from an audio source. Mixing a plurality of audio tracks, that may alternatively be referred to as audio channels, comprises combining a plurality of audio tracks, that may be from a respective plurality of audio sources, into a single output audio track (which is an output audio signal).

Masking is a psychoacoustic phenomenon that occurs when one sound, referred to as a masker, masks another sound, referred to as a maskee. The masker makes the maskee difficult to hear.

A system for mixing audio tracks is described below:
1. First, the audio signals from each track are analyzed to determine their respective levels, frequencies, and other characteristics. The analysis can be performed using digital signal processing techniques, as is known in the art.
2. Next, the levels of the audio signals are adjusted to account for inter-track auditory masking. This step may comprise manual intervention by a mix engineer.
The levels of the audio signals in the tracks that are masked by other tracks may be increased and the levels of the audio signals in the tracks that are not masked may be decreased. Other mixing techniques, such as dynamic range compression, panning and equalisation, may then be applied to further reduce the inter-track auditory masking.
3. The adjusted audio signals of the audio tracks are then combined into a single output audio signal.
4. The output audio signal is then sent to the speakers, a recording medium, or other receiver of an audio signal, depending on the audio application.

The above-described system may be operated by a mix engineer to reduce inter-track auditory masking and thereby ensure that the audio signals from each track are balanced and audible, even if some of the tracks are partially masked by others. This can create a more cohesive and enjoyable listening experience.

A system for automatically mixing audio tracks is published by ‘Automatic Minimisation of Masking in Multitrack Audio using Subgroups’; David Ronan, Zheng Ma, Paul Mc Namara, Hatice Gunes, Joshua D. Reiss; that is retrievable from https://arxiv.org/abs/1803.09960 (as viewed on 18 Dec. 2022), the entire contents of which are incorporated herein by reference. The same system is also published in the thesis Intelligent Subgrouping of Multitrack Audio, by David Ronan, that is retrievable from https://qmro.qmul.ac.uk/xmlui/handle/123456789/55527 (as viewed on 18 Dec. 2022), the entire contents of which are incorporated herein by reference. This known system for automatically mixing audio tracks is referred to herein as an ‘offline audio-mixer’. A substantial limitation of the offline audio-mixer is that it is unable to mix audio tracks in real-time.

The MPEG psychoacoustic model is a known approach to measuring masking within a single audio track. The MPEG psychoacoustic model is described in at least: Analysis of the MPEG-1Layer III (MP3) Algorithm Using MATLAB; Jayaraman J. Thiagarajan and Andreas Spanias; ISBN: 9781608458011 (paperback); ISBN: 9781608458028 (ebook); DOI 10.2200/S00382ED1V01Y201110ASE009; A Publication in the Morgan & Claypool Publishers series; SYNTHESIS LECTURES ON ALGORITHMS AND SOFTWARE IN ENGINEERING; Lecture #9; Series Editor: Andreas Spanias, Arizona State University; Series ISSN; Synthesis Lectures on Algorithms and Software in Engineering; Print 1938-1727 Electronic 1938-1735; the entire content of which is incorporated herein by reference. The MPEG psychoacoustic model is also described in at least: https://ieeexplore.org/abstract/document/388209 (as viewed on 18 Dec. 2022), the entire contents of which are incorporated herein by reference.

The MPEG psychoacoustic model is a mathematical model that simulates the human auditory system and predicts how the brain processes and perceives sound. The known use of the MPEG psychoacoustic model is for audio compression technologies, such as the MP3 format.

According to a first embodiment, there is provided a system for automatically mixing audio tracks that improves on known techniques. The system uses a psychoacoustic model to reduce the presence of masking in the output audio signal. A particular advantage of the system over the above-described offline audio-mixer, and other known techniques, is that it is able to operate in substantial real-time.

The psychoacoustic model applied by the present embodiment may be an extension of the MPEG psychoacoustic model for a single track so that the MPEG psychoacoustic model can be applied with a plurality of audio tracks. The MPEG psychoacoustic model of the present embodiment may be used to measure inter-track auditory masking by predicting how the brain will perceive the sounds from each audio track in relation to the other tracks. This can be done by analyzing the audio signals from each track and using the model to simulate the brain's response to the sounds. The model can then be used to determine which tracks are masked by others and the levels of the audio signals may be adjusted in dependence on this.

There are a number of challenges that need to be addressed in order to measure masking in a multi-track audio mix, and then to use the measurement in the implementation of an automatic mixing system.

The challenges include:
1) How to define masking on a track in a mix?
2) How to define overall masking in a mix?
3) What additional constraints to use in optimization?
4) What processing can be applied?
5) How to optimise the processing?

The above five challenges are inter-related. That is to say, one can't say if the masking metric is good until both 1) and 2) have been addressed, and one can't say if there is a good mix based on a masking metric until all five aspects have been applied.

With regard to 1), the present embodiment may extend the MPEG psychoacoustic model so that it may be used for a plurality of audio tracks. The MPEG psychoacoustic model may be used to determine a masking measurement, i.e. a measurement of the amount of masking, for each track.

With regard to 2), the present embodiment may apply a number of different techniques. A preferred technique is to sum of the squares of the masking measurements for each track. This will provide a single overall measure of masking in the mixed signals. Other techniques that may be applied include simply summing the magnitudes of all of the masking measurements, or using only the maximum masking measurement.

With regard to 3), a number of constraints may be applied that limit the processing that may be applied. For example, a constraint may be that the loudness of each track is within a certain range. In a preferred embodiment, a constraint is applied that minimises the maximum difference in loudness between any two tracks. Other examples of constraints are that, in equalisation (EQ), the maximum amount of cut and boost to apply may be set at 6 dB, and the Quality factor (Q) may be fixed in dependence on the band number.

With regard to 4), the allowable processing that may be applied is important to the effectiveness the automatic mix and the use cases to which it may be applied. In a preferred embodiment, the allowable processing comprises a slight simplification of a multiband dynamics processor, plus subgrouping and a real-time loudness normalization stage. The allowable processing may include applying gain, dynamic range compression, equalisation, dynamic equalisation and panning.

With regard to 5), a number of different optimisation algorithms may be applied. A preferred embodiment uses particle swarm optimisation. The Levenberg-Marquardt Algorithm (LMA) may also be used. A gradient descent style optimisation may also be used.

The system of the first embodiment provides a substantial real-time automatic audio mixing system for audio signals. The system uses a psychoacoustic model, that may be based on the MPEG psychoacoustic model, to measure inter-track auditory masking. The system then automatically adjusts applied audio effects, such as gain, dynamic range compression, equalisation, and panning in dependence on the measured inter-track auditory masking. The system provides a new approach to automatic audio mixing that takes into account the psychoacoustic effects of sound perception, allowing for a more natural and immersive listening experience. By using a psychoacoustic model, the system is able to accurately predict the masking threshold for each frequency band and automatically apply the appropriate audio effects to each track for reducing the masking in substantial real time. This results in a highly efficient and effective automatic mixing system that can improve the quality of the final audio output.

The audio mixing system according to the present embodiment may determine the masking on a track in a mix by extending the known MPEG masking metric to use more frequency bands. In particular, the number of frequency bands that a track is divided into may be extended to, for example, 32 bands, 64 bands or 128 bands. This improves the frequency resolution.

The audio mixing system according to the present embodiment may determine the overall masking in a mix in dependence on masking measurements in a plurality of frequency bands for each audio input track. The number of frequency bands for which a masker-to-signal ratio, MSR, measurement is determined for each audio input track may be, but is not limited to, five. Embodiments include using a different number of frequency bands for which a MSR measurement is determined. All of the MSR measurements for each audio track may be defined as values in a matrix, that may be referred to as a masking matrix.

The audio mixing system according to the present embodiment may determine and apply one or more optimization techniques to the configuration of one or more processes applied to the audio tracks. In particular, in each time window, the system may analyse the masking matrix and apply one or more audio processes such that the magnitude of most, and preferably all, of the MSR measurements is reduced relative to the magnitudes of the MSR measurements in the masking matrix of the previous time window. The applied one or more processes preferably cause the MSR measurements to converge to zero.

The inputs to the system according to the present embodiment may comprise a plurality of audio tracks.

The output of the system according to the present embodiment may be a single audio track, referred to as the output track. The output track may comprise a mix of all the input tracks. The techniques of the present embodiment may apply gain, dynamic range compression, panning and equalisation so that each of the mixed sound sources present in the output track can be heard clearly.

The operation of the system of the present embodiment is described in more detail below. The operation of the system may comprise the following processes, each of which may be implemented by an algorithm:
1) The total number of tracks to be mixed together is N. The value on N may be, for example, 2, 3, 4, 5, 6, 7, 8, 9, or larger. Preferably, N is two or more. More preferably, N is 8.
   The system may periodically automatically capture a window of audio, referred to as an audio frame, from each track. The window length may be, for example, between 10 ms and 1200 ms, and preferably between 100 ms and 1000 ms. For the section of each track in the N audio frames obtained from the respective N tracks, the below described processes 2) to 6) may be performed.
2) To measure the inter-track auditory masking for each track, the system may automatically analyse each available track in the context of a combination, such as the sum, of all the other remaining tracks. For example, when N is greater than 3, track 1 may be analysed relative to a combination of tracks 2 to N. Similarly, track 2 is analysed relative to a combination of all of track 1 and tracks 3 to N.
   The inter-track auditory masking for each track may comprises a plurality of inter-track auditory masking measurements. Each inter-track auditory masking measurement for each track may be determined in dependence on the MPEG psychoacoustic model as described above.
   Each track may be divided into a plurality of frequency bands and an inter-track auditory masking measurement determined for each frequency band. For example, each track may be linearly divided into 32 frequency bands. With a total audio bandwidth of 22050 Hz for each track, the bandwidth per frequency band is 22050 Hz/32=689 Hz. That is to say, each track may be divided into adjacent frequency bands with each frequency band having the same bandwidth of 689 Hz.
   An inter-track auditory masking measurement is then determined for each frequency band of each track. Accordingly, 32 inter-track auditory masking measurements may be determined for each track. As described above, each inter-track auditory masking measurement is obtained between the frequency band of a track and a combination of the corresponding frequency bands in all of the other tracks.
   Embodiments include applying the psychoacoustic model with each track divided into more than, or less than, 32 frequency bands. The number of bands used in the psychoacoustic model is a design decision that can be adjusted depending on the specific requirements and constraints of the application. In general, using more bands can provide more detailed and accurate modelling of the psychoacoustic properties of the audio signal, but it can also increase the computational complexity and overhead of the model.
   Whether or not it is beneficial to use more than, or less than, 32 frequency bands will depend on the specific application and the trade-offs between accuracy and performance that are acceptable.
   Embodiments also include the inter-track auditory masking measurements being determined according to the techniques described in the above-referenced offline audio-mixer.
3) The system may then map the inter-track auditory masking measurements of each of the 32 frequency bands to how the audio bands are typically divided in audio engineering. This may generate the following:
   a) Sub-bass: 20-60 Hz} Band 1
   b) Bass: 60-250 Hz} Band 1
   c) Low mid: 250-500 Hz} Band 1
   d) Mid: 500-2,000 Hz} Bands 1-4
   e) Upper Mid: 2,000-4,000 Hz} Bands 4-6
   f) Presence: 4,000-6,000 Hz} Bands 6-9
   g) Brilliance: 6,000-20,000 Hz} Bands 10-32
4) The system may then map the measurements in these bands to a multi-band equaliser. This may be, for example, a five frequency band equaliser and the mapping may be as shown below:

$$a ) 0 - 689 Hz - Bass + Low Mid = Band 1 = {M}_{1} ( dB )$$

$$b ) 689 - 2067 Hz - Mids = mean ( Bands 1 - 3 ) = {M}_{2} ( dB )$$

$$c ) 2067 - 4134 Hz - Upper Mids = mean ( Bands 4 - 6 ) = {M}_{3} ( dB )$$

$$d ) 4134 - 6201 Hz - Presence = mean ( Bands 6 - 9 ) = {M}_{4} ( dB )$$

$$e ) 6201 - 20 kHz - Brilliance = mean ( Bands 10 - 32 ) = {M}_{5} ( dB )$$

5) For each time window, the masker-to-signal ratio (MSR) may be determined in dependence on the mapped measurement values in the five frequency bands for each track. A masking matrix may be constructed comprising MSR values as shown below:

$$[ \begin{matrix}{MSR}_{11} {MSR}_{12} {MSR}_{13} … {MSR}_{1 N} \\ {MSR}_{21} {MSR}_{22} {MSR}_{23} … {MSR}_{2 N} \\ {MSR}_{31} {MSR}_{32} {MSR}_{33} … {MSR}_{3 N} \\ {MSR}_{41} {MSR}_{42} {MSR}_{43} … {MSR}_{4 N} \\ {MSR}_{51} {MSR}_{52} {MSR}_{53} … {MSR}_{5 N}\end{matrix} ]$$

Each MSR value in the above masking matrix is a measurement result of the amount of masking present in one of five frequency bands of one of the N input tracks.
   a) If the MSR value is a negative number, that means that the frequency band for that track is being masked.
   b) If the MSR value is a positive number that means that the frequency band for that track is not being masked.
   c) If the MSR value is zero, or close to zero, the frequency band for that track is audible and masked to a certain extent. This is typically the desired scenario as it is in equilibrium.
   d) The magnitude of the MSR value may indicate the extent to which a frequency band of a track is masked by one or more frequency bands of the other tracks, or the extent to which the frequency band of the track is masking one or more frequency bands in other tracks.
6) One or more techniques may be determined and applied so as to change the magnitude of one or more, and preferably all, of the MSR values in the masking matrix to be zero, or close to zero.
   For example, an equalisation (EQ) technique may be applied so as to change the magnitude of one or more, and preferably all, of the MSR values in the masking matrix to be zero, or close to zero. The EQ may apply either a boost or a cut in one or more of the bands of one or more of the tracks. The EQ may be applied with a preference for cutting over boosting. The parameters of the applied EQ may be determined iteratively, or by other techniques for determining how to change the MSR values.
   Additional, or alternative, techniques that may be applied for changing the MSR values include one or more of gain, dynamic range compression, and panning.
   One or more of the audio tracks may be more important than others. In such circumstances, each important audio track should be clearly heard. The present embodiment includes ensuring that each important audio track is clearly heard by biasing the applied technique for changing the MSR values in the masking matrix so that each important audio track is clearly heard. Ensuring that an important audio track is clearly heard may come at the expense of the audio clarity of one or more of the less important audio tracks.
   The system of the present embodiment is adaptable. For example, during the operation of the system, the number of audio tracks present may change and/or the relative importance of the present audio tracks may change. The one or more techniques that are determined and applied so as to change the magnitude of MSR values in the masking matrix may be determined in dependence on the tracks that are currently present and/or the relative importance of the tracks. The system may therefore quickly adapt to the current circumstances and operational requirements.
7) The subsequent set of N audio frames from the respective N tracks may then be processed. All of the above-described steps 1 to 6 may be repeated with the subsequent set of N audio frames, and at a later stage with further sets of audio frames after the subsequent set of N audio frames.
   For each track, the differences between how adjacent audio frames are processed may be smoothed out. For example, an exponential moving average filter may be used to smooth any differences in the EQ settings between adjacent audio frames.

Advantageously, the present embodiment provides a real-time automatic audio mixing system. The system may use level/gain, EQ or dynamic EQ, to adaptively adjust a mix based on track importance and/or perceptual masking. The perceptual masking may be determined using the MPEG masking metric.

Applications of the present embodiment may include live broadcasts in a mixing desk where there are multiple tracks of different importance. The present embodiment allows appropriate settings for each audio track to be automatically set as a fail-safe, or as an aid to a broadcasting engineer.

Applications of the present embodiment may also include live-action video games, and/or virtual reality systems, where there are different characters and different audio layers of differing importance that need to be changed based on the narrative.

Applications of the present embodiment may also include teleconferencing systems when different speakers are trying to communicate and background noise need to be filtered out.

Applications of the present embodiment may also include smart headphones that have external microphones to place importance on someone speaking to the user, the user's music, the user's telephone call or any danger noises like an approaching car etc. The less important tracks may be adaptively filtered out.

A second embodiment is described below. The second embodiment provides a system for automatically mastering an audio signal.

By way of background, mastering is the process of preparing an audio recording for release. It typically involves a variety of techniques such as equalisation, compression, and limiting, to enhance the sound of the recording and make it suitable for a specific listening environment or format. Mastering is typically the final step in the audio production process and is performed after the recording has been mixed and edited.

The goal of mastering is to improve the overall sound quality of the recording and ensure that it is consistent and balanced across the entire frequency spectrum. This may involve correcting any tonal imbalances or frequency anomalies, enhancing the perceived loudness of the recording, and ensuring that the recording is appropriate for the intended playback format or medium.

Mastering is typically performed by a mastering engineer, who has specialised knowledge and expertise in audio processing and mastering techniques. The mastering engineer will use a variety of tools and techniques, such as equalisers, compressors, and limiters, to enhance the sound of the recording and prepare it for release. The resulting mastered audio is typically the final version of the recording that will be released to the public and is often referred to as the master recording.

Harmonic-percussive source separation, HPSS, is a known technique used to separate an audio signal into its harmonic and percussive components. Harmonic content consists of pitches and tonal information, while percussive content consists of transients and non-tonal information. HPSS is a form of audio source separation, which is the process of separating an audio signal into its individual components or sources.

HPSS is typically performed using a combination of signal processing techniques, such as spectral analysis, filtering, and thresholding. The goal of HPSS is to decompose an audio signal into its harmonic and percussive components, such that each component can be processed or manipulated separately without affecting the other. This can be useful for a variety of applications, including audio editing, remixing, and mastering.

For example, in mastering, HPSS can be used to separate the harmonic and percussive components of an audio signal, and then apply different processing techniques to each component. This can allow the harmonic content to be processed for clarity and warmth, while the percussive content can be processed for punch and definition. By separating the signal into its individual components, HPSS can provide greater control and flexibility in the mastering process.

In HPSS, the residual component is the part of the audio signal that is not assigned to either the harmonic or percussive components. Harmonic content consists of pitches and tonal information, while percussive content consists of transients and non-tonal information.

As mentioned previously, the process of HPSS involves applying various signal processing techniques to the audio signal, such as spectral analysis, filtering, and thresholding, to decompose the signal into its harmonic and percussive components. However, not all of the components of the audio signal can be accurately assigned to either the harmonic or percussive components. The residual component consists of the remaining parts of the signal that cannot be accurately assigned to either component.

The residual component is typically composed of a mixture of harmonic and percussive elements and may include other components such as noise or artefacts. It is typically not as useful as the isolated harmonic and percussive components and is often discarded or ignored in further processing. The quality and characteristics of the residual component will depend on the specific implementation of the HPSS algorithm and the characteristics of the audio signal.

Loudness Units relative to Full Scale, LUFS, is a unit of measurement used to express the perceived loudness of an audio signal. It is commonly used in the audio industry to ensure that recordings have a consistent loudness and can be played back at the same volume across different playback systems and environments.

LUFS is based on the psychoacoustic principles of loudness perception, which describe how the human auditory system processes sound and how loudness is perceived. The loudness of an audio signal is determined by its spectral content and temporal characteristics, as well as the level and frequency response of the playback system. LUFS is designed to provide a consistent and standardized measure of loudness that is independent of these factors.

LUFS is commonly used in audio mastering, where it is used to ensure that the loudness of a recording is consistent and appropriate for the intended playback format or medium. It is also used in broadcast applications, where it is used to ensure that the loudness of television and radio programs is consistent and compliant with industry standards.

The second embodiment provides a system for automatically mastering an audio signal that improves on known techniques. In the second embodiment, harmonic/percussive mastering may be performed in dependence on a psychoacoustic model, such as the MPEG psychoacoustic model.

The present embodiment provides a system that allows a user to upload one or more tracks that they want to be mastered as well as the desired loudness preference for each track. The system automatically masters each track and outputs to the user an appropriately mastered audio track. The user may select a preferred file type for the output audio track.

The system according to the present embodiment may receive an input audio signal and apply a source separation technique to split the signal into harmonic, percussive and residual components. The system may then use a psychoacoustic model, that may be based on the MPEG psychoacoustic model, to determine how to reduce the amount of masking in the harmonic and percussive components. For example, in dependence on masking measurements that may be determined as described for the first embodiment, equalisation (EQ) and dynamic equalisation (DEQ) techniques may be applied to reduce, and preferably minimise, the amount of masking in the harmonic and percussive components. The applied EQ and DEQ techniques may reduce the residual noise to thereby increase the presence of harmonic and percussive components in the overall signal.

The operation of the system of the present embodiment is described in more detail below. The operation of the system may comprise the following processes, each of which may be implemented by an algorithm.

The inputs to the system may be both an audio track, such as an audio signal of a piece of musical content that has already been mixed, and also a user set desired loudness level in LUFS.

The output of the system may be an audio track that has been automatically processed by a mastering signal chain and is at the user set desired loudness level in LUFS.

The system may apply one or more algorithms that:
1. Apply a technique that separates the input audio track substantially into its harmonic and percussive components. The applied technique may be HPSS. Generally speaking, the harmonic components contribute to warmth and clarity, while the percussive components contribute to punch and definition.

Harmonic and percussive signals may be generated. The harmonic and percussive signals may be spectrums that respectively are frequency domain representations of the harmonic and percussive components of the input audio track.
2. The obtained harmonic and percussive components may be combined and subtracted from the original signal so as to determine the residual components.

This may comprise adding the harmonic and percussive signals together to generate a combined harmonic and percussive spectrum. The spectrum of the input audio track may be obtained by performing a Fourier Transform such as a FFT or DFFT. The combined harmonic and percussive spectrum may be subtracted from the spectrum of the input audio track to generate a residual signal that is the spectrum of the residual components.

An Inverse Fourier Transform may be applied to the combined harmonic and percussive spectrum to generate a time domain representation of the combined harmonic and percussive spectrum, referred to herein as THPS.

An Inverse Fourier Transform may be applied to the residual signal to generate a time domain representation of the residual signal, referred to herein as TRS.
3. A psychoacoustic model, that may be as described for the first embodiment and based on the MPEG psychoacoustic model, may then be used to determine one or more inter-signal masking values. Each inter-signal masking value may be determined in a corresponding way to the inter-track auditory masking measurement of the first embodiment, with the techniques applied between signals instead of tracks. Each inter-signal masking value may be a measure of how much these residual components are masking the harmonic and percussive components.

In particular, the psychoacoustic model may be applied between THPS and the TRS to determine one or more inter-signal masking values. When there are a plurality of inter-signal masking values, an overall inter-signal masking value may be determined.
4. EQ, DEQ and/or dynamic range compression techniques may then be determined for reducing, and preferably minimising, each inter-signal masking value and/or the overall inter-signal masking value. A numerical optimisation technique may be applied to determine the settings, i.e. configuration, of the EQ, DEQ and/or dynamic range compression techniques.
5. The EQ, DEQ and/or dynamic range compression techniques may then be applied with the determined settings to the input audio track to generate a processed audio track.
6. The system then applies gain to the processed audio track in order for it to be at the desired loudness in LUFS
7. After the gain has been applied, a mastering limiter may be applied to the processed audio track so as to avoid any unwanted clipping.

Advantageously, the system according to the present embodiment automatically masters an audio track to a user set desired loudness level in LUFS.

The present embodiment also includes variations to the above-described techniques. For example, the inter-signal masking may be measured between the residual components and only one of the harmonic and percussive components. This is appropriate if only one of the harmonic and percussive components is required and so the quality of the required component should be optimised.

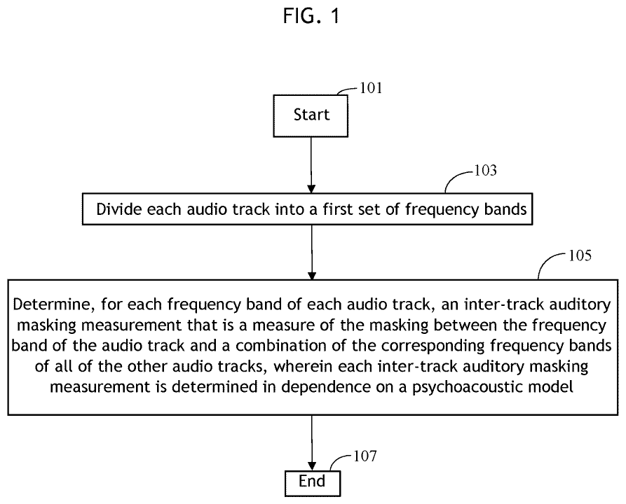

FIG. 1 shows a flowchart of a method according to an embodiment.

In step 101, the method starts.

In step 103, each audio track is divided into a first set of frequency bands.

In step 105, a determination is made, for each frequency band of each audio track, of an inter-track auditory masking measurement that is a measure of the masking between the frequency band of the audio track and a combination of the corresponding frequency bands of all of the other audio tracks, wherein each inter-track auditory masking measurement is determined in dependence on a psychoacoustic model.

In step 107, the method ends.

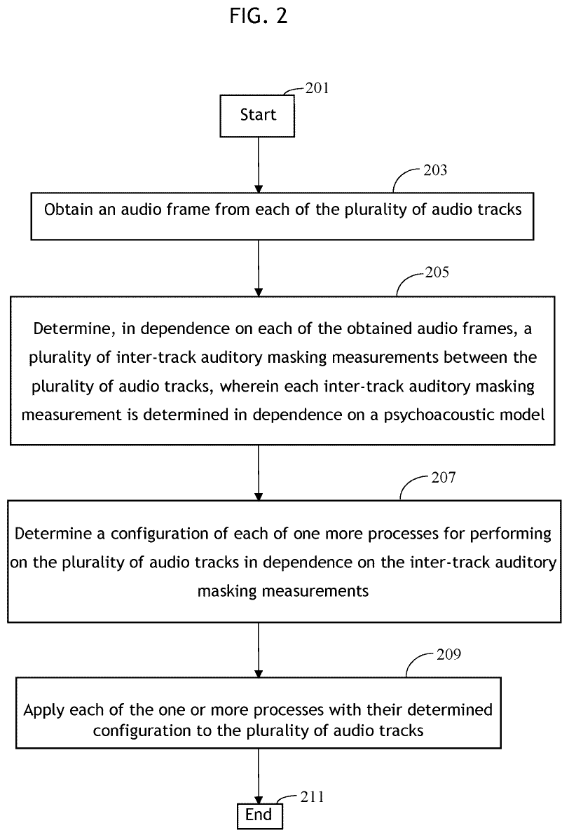

FIG. 2 shows a flowchart of a method according to an embodiment.

In step 201, the method starts.

In step 203, an audio frame is obtained from each of the plurality of audio tracks.

In step 205, a determination is made, in dependence on each of the obtained audio frames, of a plurality of inter-track auditory masking measurements between the plurality of audio tracks, wherein each inter-track auditory masking measurement is determined in dependence on a psychoacoustic model.

In step 207, a determination is made of a configuration of each of one more processes for performing on the plurality of audio tracks in dependence on the inter-track auditory masking measurements.

In step 209, each of the one or more processes are applied with their determined configuration to the plurality of audio tracks.

In step 211, the process ends.

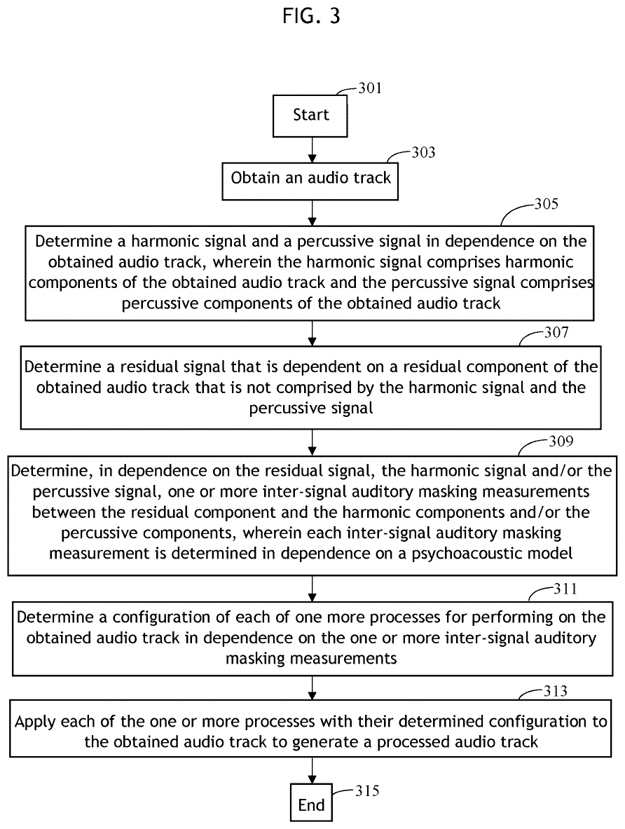

FIG. 3 shows a flowchart of a method according to an embodiment.

In step 301, the method starts.

In step 303, an audio track is obtained.

In step 305, a harmonic signal and a percussive signal are determined in dependence on the obtained audio track, wherein the harmonic signal comprises harmonic components of the obtained audio track and the percussive signal comprises percussive components of the obtained audio track.

In step 307, a residual signal is determined that is dependent on a residual component of the obtained audio track that is not comprised by the harmonic signal and the percussive signal.

In step 309, a determination is made, in dependence on the residual signal, the harmonic signal and/or the percussive signal, of one or more inter-signal auditory masking measurements between the residual component and the harmonic components and/or the percussive components, wherein each inter-signal auditory masking measurement is determined in dependence on a psychoacoustic model.

In step 311, a determination is made of a configuration of each of one more processes for performing on the obtained audio track in dependence on the one or more inter-signal auditory masking measurements.

In step 313, each of the one or more processes with their determined configuration is applied to the obtained audio track to generate a processed audio track.

In step 315, the method ends.

Embodiments include a number of modifications and variations of the techniques as described above.

In particular, embodiments have been described with reference to audio tracks. Each audio track may be a mono audio track that comprises only a single audio signal. However, embodiments may also be applied with multi-channel audio tracks that comprise a plurality of audio signals. Multi-channel audio tracks are required for spatial audio systems, stereo, surround sound, VBAP, ambisonics, and others.

In any of the above-described embodiments, when an input audio track is a multi-channel audio track, the multi-channel audio track may be converted into a mono version of the audio track and the processing for applying to the input audio track determined in dependence on the mono version of the input audio track.

The multi-channel audio track may be converted into a mono audio track by averaging all of the separate audio signals comprised by the track. The processes of embodiments, such as determining inter-track auditory masking measurements, may then be performed with the mono version of the audio track. The determined processes for apply to the input multi-channel audio track, such as for reducing masking effects, are then applied, with the same settings/configurations, to the multi-channel version of the input audio-track. The output audio track will therefore also be a multi-channel audio track.

In embodiments, each audio track may have any sample rate and bandwidth.

The flow charts and descriptions thereof herein should not be understood to prescribe a fixed order of performing the method steps described therein. Rather, the method steps may be performed in any order that is practicable. Although the present invention has been described in connection with specific exemplary embodiments, it should be understood that various changes, substitutions, and alterations apparent to those skilled in the art can be made to the disclosed embodiments without departing from the spirit and scope of the invention as set forth in the appended claims.

Methods and processes described herein can be embodied as code (e.g., software code) and/or data. Such code and data can be stored on one or more computer-readable media, which may include any device or medium that can store code and/or data for use by a computer system. When a computer system reads and executes the code and/or data stored on a computer-readable medium, the computer system performs the methods and processes embodied as data structures and code stored within the computer-readable storage medium. In certain embodiments, one or more of the steps of the methods and processes described herein can be performed by a processor (e.g., a processor of a computer system or data storage system). It should be appreciated by those skilled in the art that computer-readable media include removable and non-removable structures/devices that can be used for storage of information, such as computer-readable instructions, data structures, program modules, and other data used by a computing system/environment. A computer-readable medium includes, but is not limited to, volatile memory such as random access memories (RAM, DRAM, SRAM); and non-volatile memory such as flash memory, various read-only-memories (ROM, PROM, EPROM, EEPROM), magnetic and ferromagnetic/ferroelectric memories (MRAM, FeRAM), phase-change memory and magnetic and optical storage devices (hard drives, magnetic tape, CDs, DVDs); network devices; or other media now known or later developed that is capable of storing computer-readable information/data. Computer-readable media should not be construed or interpreted to include any propagating signals.

Embodiments include the following numbered clauses:
1. A method of determining a plurality of inter-track auditory masking measurements between a plurality of audio tracks, the method comprising:
dividing each audio track into a first set of frequency bands; and
determining, for each frequency band of each audio track, an inter-track auditory masking measurement that is a measure of the masking between the frequency band of the audio track and a combination of the corresponding frequency bands of all of the other audio tracks;
wherein each inter-track auditory masking measurement is determined in dependence on a psychoacoustic model.
2. The method according to clause 1, further comprising:
mapping, for each audio track, the inter-track auditory masking measurements determined for the first set of frequency bands to a second set of frequency bands; and determining, for each frequency band of the second set of frequency bands, a respective masker-to-signal ratio, MSR, measurement.
3. The method according to clause 1 or 2, wherein the psychoacoustic model is the MPEG psychoacoustic model.
4. The method according to any preceding clause, wherein all of the frequency bands in the first set of frequency bands have the same bandwidth.
5. The method according to any preceding clause, wherein the number of frequency bands in the first set of frequency bands is between 16 and 512, and preferably 32, 64 or 128.
6. The method according to any of clauses 2 to 5, wherein the second set of frequency bands are the bands of an equaliser.
7. The method according to any of clauses 2 to 6, wherein the number of frequency bands in the second set of frequency bands is between 3 and 10, and preferably 5.
8. The method according to any preceding clause, wherein mapping the inter-track auditory masking measurements determined for the first set of frequency bands to a second set of frequency bands comprises:
mapping the inter-track auditory masking measurements determined for the first set of frequency bands to a third set of frequency bands; and
mapping the inter-track auditory masking measurements of third set of frequency bands to the second of frequency bands;
wherein the total number of frequency bands in the third set of frequency bands is between 4 and 10, and preferably 7.
9. The method according to clause 8, wherein the third set of frequency bands includes a separate frequency band for each of sub-bass frequencies, bass frequencies, low mid frequencies, mid frequencies, upper mid frequencies, presence frequencies and brilliance frequencies.
10. The method according to any preceding clause, further comprising generating an overall masking measurement in dependence on the plurality of inter-track auditory masking measurements.
11. The method according to clause 10, wherein the overall masking measurement is determined in dependence on a combination of the plurality of inter-track auditory masking measurements.
12. The method according to any preceding clause, wherein one or more of the audio tracks is a multi-channel audio track that comprises two or more audio signals, and the method comprises:
converting each multi-channel audio track to a mono audio track; and
performing, on each mono audio track, said processes of dividing each audio track into a first set of frequency bands and determining inter-track auditory masking measurements.
13. The method according to any of clauses 2 to 12, wherein for each MSR measurement the polarity of the MSR measurement indicates if the band for that track is being masked; and/or
the magnitude of the MSR measurement indicates the extent to which the band for that track is being masked or masking.
14. The method according to any preceding clause, wherein the number of audio tracks is 3 or more, and preferably 5 or more, and more preferably 8.
15. A method of automatically mixing a plurality of audio tracks in substantial real-time, the method comprising:
obtaining an audio frame from each of the plurality of audio tracks;
determining, in dependence on each of the obtained audio frames, a plurality of inter-track auditory masking measurements between the plurality of audio tracks, wherein each inter-track auditory masking measurement is determined in dependence on a psychoacoustic model;
determining a configuration of each of one more processes for performing on the plurality of audio tracks in dependence on the inter-track auditory masking measurements; and
applying each of the one or more processes with their determined configuration to the plurality of audio tracks.
16. The method according to clause 15, wherein the audio frame is a time window.
17. The method according to clause 15 or 16, wherein the length of the time window is between 10 ms and 1200 ms, and preferably between 100 ms and 1000 ms.
18. The method according to any of clauses 15 to 17, wherein the plurality of inter-track auditory masking measurements are determined in dependence on the method of any of clauses 1 to 13.
19. The method according to clause 18 when dependent on clause 10, wherein the determination of a configuration of each of the one or more processes for performing on the plurality of audio tracks reduces the overall masking measurement.
20. The method according to any of clauses 15 to 19, further comprising obtaining data on the relative importance of the audio tracks; and
wherein the determination of a configuration of each of the one or more processes for performing on the plurality of audio tracks is performed so that the audible clarity of the more important audio tracks is prioritised over that of the less important tracks.
21. The method according to any of clauses 15 to 20, wherein the applied one or more processes on the plurality of audio tracks include one or more of applying gain, dynamic range compression, equalisation, dynamic equalisation and panning.
22. The method according to any of clauses 15 to 21, wherein the method further comprises obtaining further audio frames; and
repeating, for the further audio frames, the processes of determining a plurality of inter-track auditory masking measurements, determining a configuration of each of one more processes for performing on the plurality of audio tracks in dependence on the inter-track auditory masking measurements, and applying each of the one or more processes with their determined configuration to the plurality of audio tracks.
23. The method according to clause 22, further comprising applying a smoothing to differences in the determined configuration of one or more processes applied to adjacent audio frames.
24. The method according to any of clauses 15 to 23, wherein one or more of the audio tracks is a multi-channel audio track that comprises two or more audio signals, and the method comprises:
converting each multi-channel audio track to a mono audio track;
determining the configuration of each of one more processes for performing on each multi-channel audio track in dependence on each corresponding mono audio track; and
applying each of the one or more processes with their determined configuration to each corresponding multi-channel audio track.
25. A method of automatically mastering an audio track, the method comprising: obtaining an audio track;
determining a harmonic signal and a percussive signal in dependence on the obtained audio track, wherein the harmonic signal comprises harmonic components of the obtained audio track and the percussive signal comprises percussive components of the obtained audio track;
determining a residual signal that is dependent on a residual component of the obtained audio track that is not comprised by the harmonic signal and the percussive signal;
determining, in dependence on the residual signal, the harmonic signal and/or the percussive signal, one or more inter-signal auditory masking measurements between the residual component and the harmonic components and/or the percussive components, wherein each inter-signal auditory masking measurement is determined in dependence on a psychoacoustic model;
determining a configuration of each of one more processes for performing on the obtained audio track in dependence on the one or more inter-signal auditory masking measurements; and
applying each of the one or more processes with their determined configuration to the obtained audio track to generate a processed audio track.
26. The method according to clause 25, further comprising receiving a user defined loudness level for the obtained audio track; and
applying gain to the processed audio track in dependence on the user defined loudness level.
27. The method according to any of clauses 25 or 26, wherein the one or more of inter-signal auditory masking measurements are determined in dependence on the method of any of clauses 1 to 13.
28. The method according to any of clauses 25 to 27, wherein determining a harmonic signal and a percussive signal in dependence on the obtained audio track comprises performing a harmonic-percussive source separation process. HPSS.
29. The method according to any of clauses 26 to 28, wherein
the received user defined loudness level is in loudness units relative to full scale, LUFS; and
the applied gain to the processed audio track provides the user defined loudness level in LUFS.
30. The method according to any of clauses 25 to 29, wherein the applied one or more processes on the obtained audio track include equalisation and/or dynamic equalisation.
31. The method according to any of clauses 25 to 30, wherein applying the one or more on the obtained audio track reduces the inter-signal auditory masking.
32. The method according to any of clauses 25 to 31, further comprising using a numerical optimisation technique to determine the configuration of each of the one more processes applied to the obtained audio track.
33. A computer program comprising instructions that, when executed in a computing system, cause the computing system to perform the method according to any of clauses 1 to 32.
34. A computer system configured to perform the method of any of clauses 1 to 32.

1-25. (canceled)

26. A method of automatically mastering an audio track, the method comprising:
obtaining an audio track;
determining a harmonic signal and a percussive signal in dependence on the obtained audio track, wherein the harmonic signal comprises harmonic components of the obtained audio track and the percussive signal comprises percussive components of the obtained audio track;
determining a residual signal that is dependent on a residual component of the obtained audio track that is not comprised by the harmonic signal and the percussive signal;
determining, in dependence on the residual signal, the harmonic signal and/or the percussive signal, one or more inter-signal auditory masking measurements between the residual component and the harmonic components and/or the percussive components, wherein each inter-signal auditory masking measurement is determined in dependence on a psychoacoustic model;
determining a configuration of each of one more processes for performing on the obtained audio track in dependence on the one or more inter-signal auditory masking measurements; and
applying each of the one or more processes with their determined configuration to the obtained audio track to generate a processed audio track.

27. The method according to claim 26, further comprising receiving a user defined loudness level for the obtained audio track; and
applying gain to the processed audio track in dependence on the user defined loudness level.

28. The method according to claim 26, wherein the one or more of inter-signal auditory masking measurements are determined in dependence on a method of determining a plurality of inter-track auditory masking measurements between a plurality of audio tracks, the method of determining a plurality of inter-track auditory masking measurements comprising:
dividing each audio track into a first set of frequency bands; and
determining, for each frequency band of each audio track, an inter-track auditory masking measurement that is a measure of the masking between the frequency band of the audio track and a combination of the corresponding frequency bands of all of the other audio tracks;
wherein each inter-track auditory masking measurement is determined in dependence on a psychoacoustic model.

29. The method according to claim 26, wherein the one or more of inter-signal auditory masking measurements are determined in dependence on a method of determining a plurality of inter-track auditory masking measurements between a plurality of audio tracks, the method of determining a plurality of inter-track auditory masking measurements comprising:
dividing each audio track into a first set of frequency bands; and
determining, for each frequency band of each audio track, an inter-track auditory masking measurement that is a measure of the masking between the frequency band of the audio track and a combination of the corresponding frequency bands of all of the other audio tracks;
wherein each inter-track auditory masking measurement is determined in dependence on a psychoacoustic model; and
the method of determining a plurality of inter-track auditory masking measurements further comprises:
mapping, for each audio track, the inter-track auditory masking measurements determined for the first set of frequency bands to a second set of frequency bands; and
determining, for each frequency band of the second set of frequency bands, a respective masker-to-signal ratio, MSR, measurement.

30. The method according to claim 26, wherein the one or more of inter-signal auditory masking measurements are determined in dependence on a method of determining a plurality of inter-track auditory masking measurements between a plurality of audio tracks, the method of determining a plurality of inter-track auditory masking measurements comprising:
dividing each audio track into a first set of frequency bands; and
determining, for each frequency band of each audio track, an inter-track auditory masking measurement that is a measure of the masking between the frequency band of the audio track and a combination of the corresponding frequency bands of all of the other audio tracks;
wherein each inter-track auditory masking measurement is determined in dependence on a psychoacoustic model; and
the method of determining a plurality of inter-track auditory masking measurements further comprises:
mapping, for each audio track, the inter-track auditory masking measurements determined for the first set of frequency bands to a second set of frequency bands; and
determining, for each frequency band of the second set of frequency bands, a respective masker-to-signal ratio, MSR, measurement;
wherein the psychoacoustic model is the MPEG psychoacoustic model.

31. The method according to claim 26, wherein the one or more of inter-signal auditory masking measurements are determined in dependence on a method of determining a plurality of inter-track auditory masking measurements between a plurality of audio tracks, the method of determining a plurality of inter-track auditory masking measurements comprising:
dividing each audio track into a first set of frequency bands; and
determining, for each frequency band of each audio track, an inter-track auditory masking measurement that is a measure of the masking between the frequency band of the audio track and a combination of the corresponding frequency bands of all of the other audio tracks;
wherein each inter-track auditory masking measurement is determined in dependence on a psychoacoustic model; and
the method of determining a plurality of inter-track auditory masking measurements further comprises:
mapping, for each audio track, the inter-track auditory masking measurements determined for the first set of frequency bands to a second set of frequency bands; and
determining, for each frequency band of the second set of frequency bands, a respective masker-to-signal ratio, MSR, measurement;
wherein the psychoacoustic model is the MPEG psychoacoustic model; and
wherein the second set of frequency bands are the bands of an equaliser.

32. The method according to claim 26, wherein the one or more of inter-signal auditory masking measurements are determined in dependence on a method of determining a plurality of inter-track auditory masking measurements between a plurality of audio tracks, the method of determining a plurality of inter-track auditory masking measurements comprising:
dividing each audio track into a first set of frequency bands; and
determining, for each frequency band of each audio track, an inter-track auditory masking measurement that is a measure of the masking between the frequency band of the audio track and a combination of the corresponding frequency bands of all of the other audio tracks;
wherein each inter-track auditory masking measurement is determined in dependence on a psychoacoustic model; and
the method of determining a plurality of inter-track auditory masking measurements further comprises:
mapping, for each audio track, the inter-track auditory masking measurements determined for the first set of frequency bands to a second set of frequency bands; and
determining, for each frequency band of the second set of frequency bands, a respective masker-to-signal ratio, MSR, measurement;
wherein the psychoacoustic model is the MPEG psychoacoustic model;
wherein the second set of frequency bands are the bands of an equaliser; and
wherein mapping the inter-track auditory masking measurements determined for the first set of frequency bands to a second set of frequency bands comprises:
mapping the inter-track auditory masking measurements determined for the first set of frequency bands to a third set of frequency bands; and
mapping the inter-track auditory masking measurements of third set of frequency bands to the second of frequency bands;
wherein the total number of frequency bands in the third set of frequency bands is between 4 and 10, and preferably 7.

33. The method according to claim 26, wherein the one or more of inter-signal auditory masking measurements are determined in dependence on a method of determining a plurality of inter-track auditory masking measurements between a plurality of audio tracks, the method of determining a plurality of inter-track auditory masking measurements comprising:
dividing each audio track into a first set of frequency bands; and
determining, for each frequency band of each audio track, an inter-track auditory masking measurement that is a measure of the masking between the frequency band of the audio track and a combination of the corresponding frequency bands of all of the other audio tracks;
wherein each inter-track auditory masking measurement is determined in dependence on a psychoacoustic model; and
the method of determining a plurality of inter-track auditory masking measurements further comprises:
mapping, for each audio track, the inter-track auditory masking measurements determined for the first set of frequency bands to a second set of frequency bands; and
determining, for each frequency band of the second set of frequency bands, a respective masker-to-signal ratio, MSR, measurement;
wherein the psychoacoustic model is the MPEG psychoacoustic model;
wherein the second set of frequency bands are the bands of an equaliser; and
wherein mapping the inter-track auditory masking measurements determined for the first set of frequency bands to a second set of frequency bands comprises:
mapping the inter-track auditory masking measurements determined for the first set of frequency bands to a third set of frequency bands; and
mapping the inter-track auditory masking measurements of third set of frequency bands to the second of frequency bands;
wherein the total number of frequency bands in the third set of frequency bands is between 4 and 10, and preferably 7;
wherein the method of determining a plurality of inter-track auditory masking measurements comprises generating an overall masking measurement in dependence on the plurality of inter-track auditory masking measurements.

34. The method according to claim 26, wherein the one or more of inter-signal auditory masking measurements are determined in dependence on a method of determining a plurality of inter-track auditory masking measurements between a plurality of audio tracks, the method of determining a plurality of inter-track auditory masking measurements comprising:
dividing each audio track into a first set of frequency bands; and
determining, for each frequency band of each audio track, an inter-track auditory masking measurement that is a measure of the masking between the frequency band of the audio track and a combination of the corresponding frequency bands of all of the other audio tracks;
wherein each inter-track auditory masking measurement is determined in dependence on a psychoacoustic model; and
the method of determining a plurality of inter-track auditory masking measurements further comprises:
mapping, for each audio track, the inter-track auditory masking measurements determined for the first set of frequency bands to a second set of frequency bands; and
determining, for each frequency band of the second set of frequency bands, a respective masker-to-signal ratio, MSR, measurement;
wherein the psychoacoustic model is the MPEG psychoacoustic model;
wherein the second set of frequency bands are the bands of an equaliser; and
wherein mapping the inter-track auditory masking measurements determined for the first set of frequency bands to a second set of frequency bands comprises:
mapping the inter-track auditory masking measurements determined for the first set of frequency bands to a third set of frequency bands; and
mapping the inter-track auditory masking measurements of third set of frequency bands to the second of frequency bands;
wherein the total number of frequency bands in the third set of frequency bands is between 4 and 10, and preferably 7;
wherein the method of determining a plurality of inter-track auditory masking measurements comprises generating an overall masking measurement in dependence on the plurality of inter-track auditory masking measurements;
wherein one or more of the audio tracks is a multi-channel audio track that comprises two or more audio signals, and the method of determining a plurality of inter-track auditory masking measurements comprises:
converting each multi-channel audio track to a mono audio track; and
performing, on each mono audio track, said processes of dividing each audio track into a first set of frequency bands and determining inter-track auditory masking measurements.

35. The method according to claim 26, wherein determining a harmonic signal and a percussive signal in dependence on the obtained audio track comprises performing a harmonic-percussive source separation process. HPSS.

36. The method according to claim 26, wherein
the received user defined loudness level is in loudness units relative to full scale, LUFS; and
the applied gain to the processed audio track provides the user defined loudness level in LUFS.

37. The method according to claim 26, wherein the applied one or more processes on the obtained audio track include equalisation and/or dynamic equalisation.

38. The method according to claim 26, wherein applying the one or more processes on the obtained audio track reduces the inter-signal auditory masking.

39. The method according to claim 26, further comprising using a numerical optimisation technique to determine the configuration of each of the one more processes applied to the obtained audio track.

40. A computer program comprising instructions that, when executed in a computing system, cause the computing system to perform the method according to claim 26.

41. A computer system configured to perform the method of claim 26.
